(19) United States
(12) Patent Application Publication
(10) Pub. No.: US 2010/0080276 A1
(43) Pub. Date: Apr. 1, 2010

(54) METHOD FOR NON-PILOT TONE DATA-AIDED CARRIER FREQUENCY TRACKING

(75) Inventors: Syang-Myau Hwang, Cupertino, CA (US); Lin Yang, Fremont, CA (US); Jun Lu, Saratoga, CA (US); Shue-Lee Chang, San Jose, CA (US)

Correspondence Address: FRANK F. TIAN, 331-4A THIRD AVENUE, LONG BEACH, NJ, 07740, US

(73) Assignee: LEGEND SILICON CORP., Fremont, CA (US)

(21) Appl. No.: 12/239,786

(22) Filed: Sep. 28, 2008

(51) Int. Cl. H03K 5/159

(52) U.S. Cl. 375/232

(57) ABSTRACT

A method comprising the steps of providing a slicer for slicing real values of an equalizer output; and cross correlating an equalizer input with an output of the slicer is provided.

### CROSS-REFERENCE TO OTHER APPLICATIONS

The following applications of common assignee and filed on the same day herewith are related to the present application, and are herein incorporated by reference in their entireties:

U.S. patent application Ser. No. ______ with attorney docket number LSFFT-110.

U.S. patent application Ser. No. ______ with attorney docket number LSFFT-103.

U.S. patent application Ser. No. ______ with attorney docket number LSFFT-104.

U.S. patent application Ser. No. ______ with attorney docket number LSFFT-105.

U.S. patent application Ser. No. ______ with attorney docket number LSFFT-106.

U.S. patent application Ser. No. ______ with attorney docket number LSFFT-107.

### FIELD OF THE INVENTION

The present invention relates generally to communication systems, more specifically the present invention relates to a method for non-pilot tone data-aided carrier frequency tracking.

### BACKGROUND

Electronic equipment and supporting software applications typically involve signal processing. For example, home theater, computer graphics, medical imaging and telecommunications all rely on signal-processing technology. Signal processing requires fast math in complex, but repetitive algorithms. Many applications require computations in real-time, i.e., the signal is a continuous function of time, which need be sampled and converted to digital, for numerical processing. A signal processor has to execute algorithms performing discrete computations on the samples as they arrive. The architecture of a digital signal processor (DSP) is optimized to handle such algorithms. The characteristics of a good signal processing engine typically may include fast, flexible arithmetic computation units, unconstrained data flow to and from the computation units, extended precision and dynamic range in the computation units, dual address generators, efficient program sequencing, and ease of programming.

For wireless implementations, time domain multi-path effect exists, a digital filter such as a finite impulse response (FIR) filter is required to filter out the desired information. Therefore, it is desirous to improve digital filter circuit structure with a method for non-pilot tone data-aided carrier frequency tracking.

### SUMMARY OF THE INVENTION

A method for non-pilot tone data-aided carrier frequency tracking in a communication system is provided.

A method for non-pilot tone data-aided carrier frequency tracking in a variable sideband (VSB) receiver is provided.

A method for non-pilot tone data-aided carrier frequency tracking in a multi-leveled variable sideband (VSB) receiver such as a receiver for Advanced Television Systems Committee (ATSC) system is provided.

A method comprising the steps of providing a slicer for slicing real values of an equalizer output; and cross correlating an equalizer input with an output of the slicer is provided.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of an equalizer structure in accordance with some embodiments of the invention.

FIG. 2 is flowchart in accordance with some embodiments of the invention.

FIG. 3 is an example of a digital receiver in accordance with some embodiments of the invention.

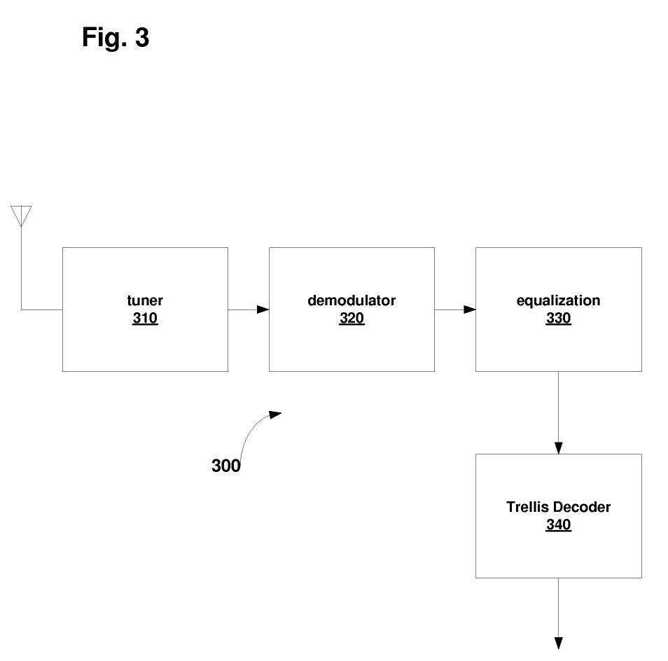

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a method for non-pilot tone data-aided carrier frequency tracking. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of using known sequences within the guard intervals being used for non-pilot tone data-aided carrier frequency tracking. The non-processor circuits may include, but are not limited to, a radio receiver, a radio transmitter, signal drivers, clock circuits, power source circuits, and user input devices. As such, these functions may be interpreted as steps of a method to non-pilot tone data-aided carrier frequency tracking. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

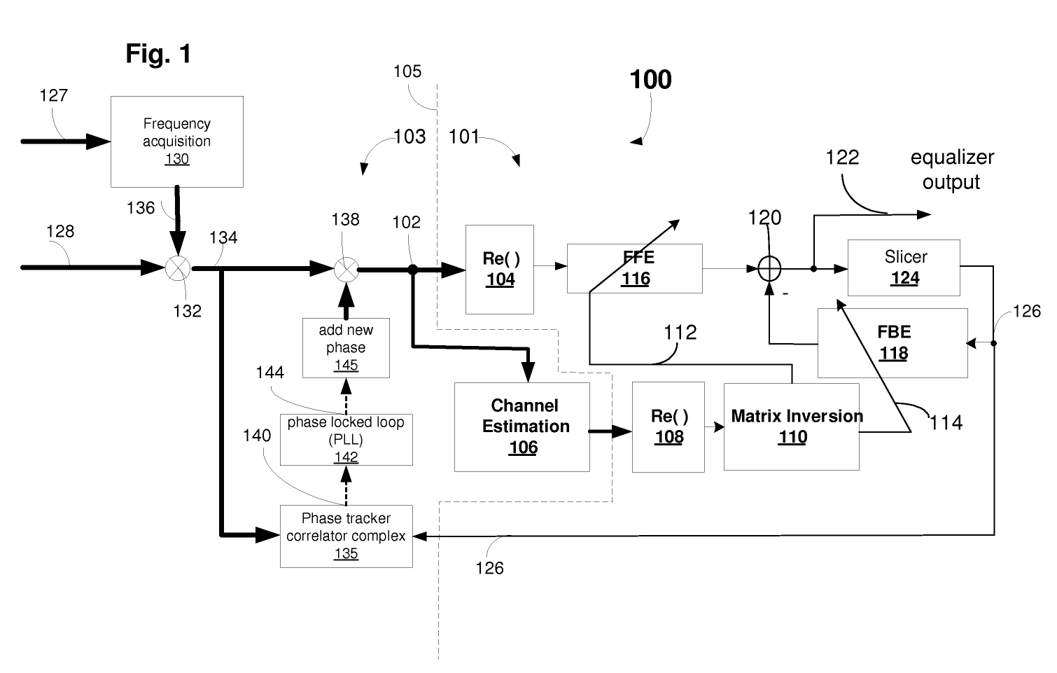

Referring to FIG. 1, a non-pilot tone data-aided carrier frequency tracking block diagram 100 is shown. Block diagram 100 comprises a first portion 101 for real signal part processing and a second portion 103 for the typical complex signal comprising both real and imaginary parts. An imaginary broken line 105 roughly divides the first portion 101 and the second portion 103. Note that the complex signal paths are depicted in boldfaced or thick black line, whereas the real signal paths are depicted in ordinary or thinner block lines. In addition, thick broken lines denote phase information.

Referring to the first portion 101, an equalizer input 102 is both input into a real part extractor 104 and a channel estimation block 106. In real part extractor 104, the real portion (versus the imaginary portion of a complex signal) of input 102 is extracted. In channel estimation block 106, both real and imaginary portions of the channel estimation block 106 are subjected to channel estimation. The estimated information is fed into real part extractor 108, the real portion (versus the imaginary portion) of input estimated information is extracted. In turn, the real portion of the estimated information is input into a matrix inversion block 110, wherein a matrix denoting the real portion of the estimated information is inverted.

Matrix inversion block 110 generates two adjustment paths, a first path 112 and a second path 114. First path 112 adjusts a feed forward equalizer block (FFE) 116, which receives the real portion of the equalizer input 102 extracted by block 104. Second path 114 adjusts a feedback equalizer block (FBE) 118, which also receives sliced information from a slicer 124. The outputs of both FFE and 116 and FBE 118 are input into an adder 120. The added inputs are the equalizer output 122. Output 122 is further subjected to slicer 124 and supplied to FBE 118. The output 126 of the slicer 124 is both fed to FBE 118 and the second portion 103.

Referring to the second portion 103, frequency acquisition input 128 to block diagram 100 is input into both a first multiplier 132 and a phase tracker correlation complex block 135 for phase tracking. A known sequence 127 is initially input into a frequency acquisition block 130 for the acquisition of frequency. The output 136 of the acquired frequency of block 130 is fed into the first multiplier 132.

As can be seen, block 135 receives real signals from both the first portion 101 or signal 126 and complex signals or signal 134 from the second portion 103. From the first portion 101, output 126 of the slicer 124 having real value is input into block 134. From the second portion 103, output of the acquired frequency of block 136 having complex values multiplies with front end data 128 with the product 134 used as input into block 135.

As can be appreciated, the output 136 of the acquired frequency of block 130 is derived from known sequence 127 to block diagram 100. In other words, a phase value 140 relating to a phase error can be obtained by doing a cross correlation between frontend data 128 with coarse frequency correlation 135 and equalizer slicer output 126. Phase value 140 is further input into a phase locked loop (PLL) 142 for a phased locked or smoother phase value φ 144. In other words, PLL 142 tracks the phase error. Angular value φ 144, in turn, is input into a block 146 to add new phase. Block 146 processes the phase value φ 144 and outputs a complex phase error e^{-jφ} 146. Phase error e^{-jφ} 146 forms an input to a second multiplier 138. Second multiplier 138 further receives a multiplied signal 134 from first multiplier 132.

First multiplier 132 further receives a frequency residual frequency signal 136. Residual frequency signal 136 and the acquired frequency of block 130 are multiplied by first multiplier 132. First multiplier 132 multiplies with front end data 128 that form the signal 134. The output of the first multiplier 132 or the frequency residual signal 134 formed the input 134 to second multiplier 138.

As can be appreciated, the characteristics of this frequency tracking loop 100 is that it is independent of embedded known sequences such as PN511 or polite tone disclosed in a paper by Jingsong Xia, entitled “A Carrier Recovery Approach for ATSC Receivers”, IEEE Trans. on Broadcasting, Vol. 54, No. 1, pp. 131-139, March 2008. In addition, by applying cross correlation, using diagram 100 can calculate phase error in real-time as calculations are reduced by using substantially real parts in first portion 101.

The characteristics of this frequency tracking loop is that it is not dependent upon embedded known sequences such as known sequence 127. Further cross correlation is applied such that phase error is calculated in real-time. In addition, the phase error is obtained by doing a cross correlation between equalizer input and equalizer slicer output. Then a PLL is used to track the phase error.

The operations of non-pilot tone data-aided carrier frequency tracking device 100 are as follows. Use residual frequency signal a known sequence 127 initializes the frequency acquisition block 130 thereby generating the output 136 to initialize device 100 before it processes front end data 128. Upon initialization, device 100 receives front end data 128 for processing by device 100 as described supra.

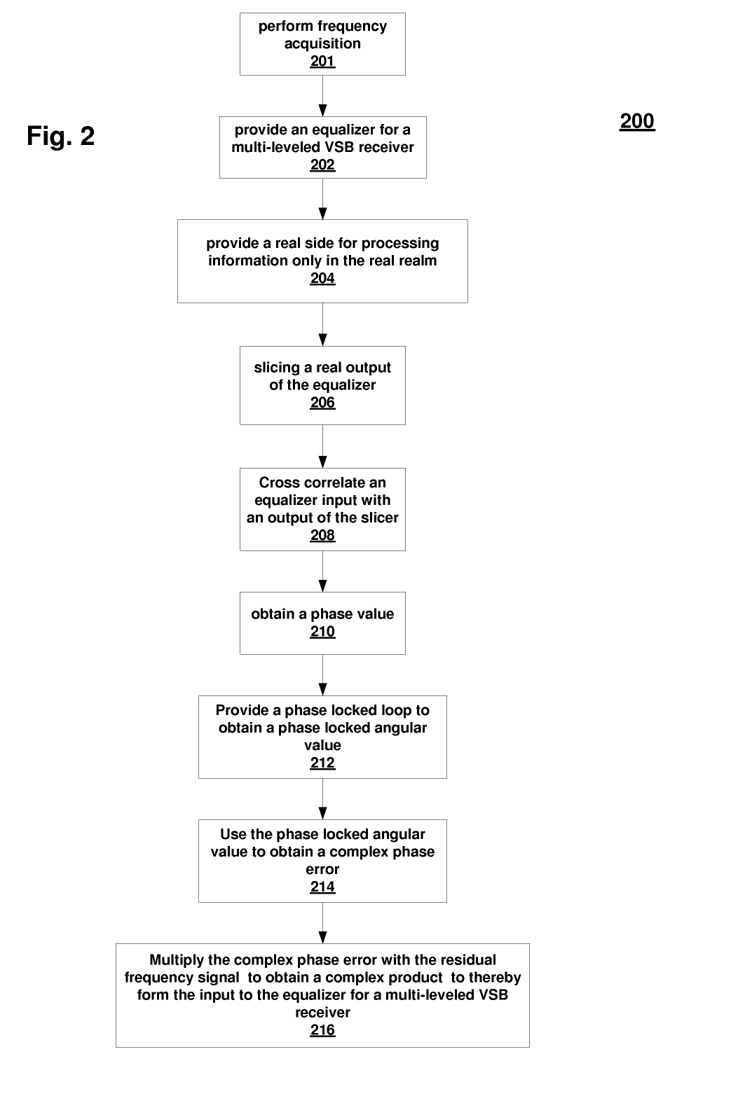

Referring to FIG. 2, a flow chart 200 depicting the training process is shown. An equalizer for a multi-leveled VSB receiver is provided (Step 202). A real side for processing information only in the real realm is provided (Step 204). Initialize a non-pilot tone data-aided carrier frequency tracking device before processing front end data (Step 204). A slicer slicing a real output of the equalizer is provided (Step 206). Cross correlate an equalizer input with an output of the slicer (Step 208). The equalizer input is derived from front end data of a multi-leveled variable sideband communications system. A phase value is obtained as a result of the cross correlation (Step 210). Provide a phase locked loop to obtain a phase locked angular value derived from the phase value (Step 212). Use the phase locked angular value to obtain a complex phase error (Step 214). Multiply the complex phase error with the equalizer input to obtain a complex product for further real part processing to derive the slicer output (Step 216). The decision feedback equalizer (DFE) of the present invention may be a non-updated DFE. The nature of non-updated DFE determines that the training process is necessary.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. A method comprising the steps of:
providing a slicer for slicing real values of an equalizer output; and
cross correlating an equalizer input with an output of the slicer.

2. The method of claim 1 further comprising the step of obtaining a phase value.

3. The method of claim 2 further comprising the step of providing a phase locked loop to obtain a phase locked angular value derived from the phase value.

4. The method of claim 3 further comprising the step of using the phase locked angular value to obtain a complex phase error.

5. The method of claim 4 further comprising the step of multiplying the complex phase error with the equalizer input to obtain a complex product for further real part processing to derive the slicer output.

6. The method of claim 1, wherein the equalizer input is derived from front end data of a multi-leveled variable sideband communications system.

7. A receiver comprises a method comprising the steps of:
providing a slicer for slicing real values of an equalizer output; and
cross correlating an equalizer input with an output of the slicer.

8. The receiver of claim 7, wherein the method further comprising the step of obtaining a phase value.

9. The receiver of claim 8, wherein the method further comprising the step of providing a phase locked loop to obtain a phase locked angular value derived from the phase value.

10. The receiver of claim 9, wherein the method further comprising the step of using the phase locked angular value to obtain a complex phase error.

11. The receiver of claim 8, wherein the method further comprising the step of multiplying the complex phase error with the equalizer input to obtain a complex product for further real part processing to derive the slicer output.

12. The receiver of claim 7, wherein the equalizer input is derived from front end data of a multi-leveled variable sideband communications system.

13. The receiver of claim 7 is a variable sideband receiver.

14. The receiver of claim 7 is a multileveled, variable sideband receiver.
